(19) United States
(12) Patent Application Publication
(10) Pub. No.: US 2015/0214502 A1
(43) Pub. Date: Jul. 30, 2015

(54) DISPLAY DEVICE AND MANUFACTURING METHOD OF THE DISPLAY DEVICE

(71) Applicant: Japan Display Inc., Tokyo (JP)

(72) Inventor: Toshihiro SATO, Tokyo (JP)

(21) Appl. No.: 14/600,891

(22) Filed: Jan. 20, 2015

(30) Foreign Application Priority Data
Jan. 27, 2014 (JP) 2014-012466

(51) Int. Cl. H01L 51/52; H01L 51/56; H01L 27/32

(52) U.S. Cl. CPC H01L 51/5237; H01L 27/32; H01L 51/56

(57) ABSTRACT

A display device includes a first substrate including a display region arranged with a plurality of pixels having a light emitting element respectively, a second substrate facing the first substrate, a spacer arranged between the first substrate and the second substrate, and a seal component including glass, bonding together the first substrate and second substrate, arranged on the exterior side of the display region and protruding further to the exterior side than an end part of the first substrate or second substrate.

### CROSS REFERENCE TO RELATED APPLICATIONS

This application is based upon and claims the benefit of priority from the prior Japanese Patent Application No. 2014-012466, filed on Jan. 27, 2014, the entire contents of which are incorporated herein by reference.

### FIELD

The present invention is related to a display device and a method of manufacturing the display device. In particular, the present invention is related to a display device in which a substrate formed with a light emitting element and an opposing substrate are sealed with a glass frit and a method of manufacturing the display device.

### BACKGROUND

In recent years, in a light emitting display device for mobile purposes, there is a strong demand for high resolution and low power consumption. Display devices which use a liquid crystal display device (LCD) or organic light-emitting diode (OLED) such an organic EL display device or electronic paper etc are being adopted.

Among these, because an organic EL display device does not require a back light or polarizing plate which were necessary in liquid crystal devices, it is possible to form a display device just with a thin film. In addition, it is possible to realize a display device capable of bending (flexible). Furthermore, since these display devices do not use a glass substrate, they are display devices which are light and difficult to break. For these reasons, organic EL display devices are attracting a lot of attention. In addition, in an organic EL display device of a medium/small size, Display devices with a narrow frame are being demanded in order to reduce the size of the display device while maintaining the size of the display.

In order to achieve a narrow frame, it is necessary to reduce the area of the periphery region of the display device. In order to achieve this, it is necessary to narrow the width of a seal component arranged in the periphery region and reduce as much as possible the area dedicated to the seal component.

Here, a light emitting element such as an organic EL element arranged in each pixel of an organic EL display device is known to degrade when exposed to oxygen or water which decreases light emitting efficiency. In order to solve this problem for example, a display device is disclosed in Japanese Laid Open Patent 2007-194184 in which a sealing structure with high air sealing properties is disclosed by bonding a substrate arranged with a light emitting element and an opposing substrate which faces the substrate using a glass frit.

However, a method is disclosed in Japanese Laid Open Patent 2007-194184 in which a glass frit is coated on the surface of a substrate or opposing substrate arranged with a transistor layer or light emitting layer and both substrates are bonded together. In this method, because it is necessary to consider the width when coating the glass frit and margin of alignment accuracy, it is necessary to increase the area required to arrange the glass frit. Furthermore, when fusing by local heating the glass frit using laser radiation etc, heat generated by laser radiation is sometimes transmitted to the light emitting element of a pixel arranged in a display region which cause degradation of the light emitting element, thereby it is necessary to secure a constant distance between the glass frit and display region. For these reasons, reduction of a periphery region is restricted.

### SUMMARY

A display device according to one embodiment of the present invention includes a first substrate including a display region arranged with a plurality of pixels having a light emitting element respectively, a second substrate facing the first substrate, a spacer arranged between the first substrate and the second substrate, and a seal component including glass, bonding together the first substrate and second substrate, arranged on the exterior side of the display region and protruding further to the exterior side than an end part of the first substrate or second substrate.

In another aspect, the seal component may be arranged on one part of a side surface of the first substrate or second substrate.

In another aspect, the seal component may be sandwiched between the first substrate and second substrate.

In another aspect, the spacer may be formed from an inorganic material.

In another aspect, the second substrate includes a light shielding layer having an aperture part corresponding to the pixel, a color filter including a pigment layer and being arranged at least in the aperture part, and an inorganic insulation layer covering at least the upper surface and an end part of the color filter, wherein the seal component bonds the first substrate and second substrate the display region and color filter facing each other, the color filter is arranged on the interior side of the seal component, and the light emitting element is exposed in a space part enclosed by the first substrate, the second substrate and seal component.

In another aspect, the display device may include a resin layer covering the seal component and arranged contacting a part of a side surface of the first substrate or second substrate.

In another aspect, a dew point temperature of the space part may be −70° C. or less.

In another aspect, an oxygen concentration of the space part may be 1 ppm or less.

A manufacturing method of a display device according to one embodiment of the present invention includes forming a light emitting element in a display region arranged with a plurality of pixels in a first substrate, bonding the first substrate and a second substrate facing the first substrate via a spacer, forming a seal component including glass, the seal component being arranged on the exterior side of the display region and protruding further to the exterior than and end part of the first substrate or second substrate, irradiating a laser from a surface side of the first substrate or second substrate to fuse the seal component.

In another aspect, the seal component may be formed on a part of a side surface of the first substrate or second substrate.

In another aspect, the seal component may be sandwiched by the first substrate or second substrate.

In another aspect, the laser may be irradiated roughly parallel on a surface of the first substrate and second substrate.

In another aspect, the laser may be irradiated so as to form a sharp angle with respect to one edge of the first substrate and second substrate in a planar view of the first substrate and second substrate.

In another aspect, a plurality of lasers may be irradiated in the same process on a plurality of pairs of substrates formed by bonding a plurality of the first substrates and a plurality of second substrates.

In another aspect, a plurality of the seal components may be formed in the same process on a plurality of pairs of substrates.

In another aspect, the seal component may be formed under an atmosphere in which a dew point temperature is −70° C. or less.

In another aspect, the seal component may be formed under an atmosphere in which an oxygen concentration is 1ppm or less.

### BRIEF DESCRIPTION OF THE DRAWINGS

FIG. 1 is a diagram showing a perspective view of a display device in embodiment one of the present invention;

FIG. 2 is a diagram showing a planar view of a display device in embodiment one of the present invention;

FIG. 3 is a diagram showing a cross-sectional view of the line A-B in a display device in embodiment one of the present invention;

FIG. 4 is a diagram showing a cross-sectional view of the line C-D in a display device in embodiment one of the present invention;

FIG. 5 is a diagram showing a cross-sectional view of the line A-B in a display device in a modified example one of embodiment one of the present invention;

FIG. 6 is a diagram showing a cross-sectional view of the line A-B in a display device in a modified example two of embodiment one of the present invention;

FIG. 7 is a diagram showing a cross-sectional view of the line A-B in a display device in embodiment two of the present invention;

FIG. 8 is a diagram showing a cross-sectional view of the line C-D in a display device in embodiment two of the present invention;

FIG. 9 is a diagram showing a planar view of a display device in embodiment three of the present invention;

FIG. 10 is a diagram showing a planar view of a display device in a modified example one of embodiment three of the present invention;

FIG. 11 is a diagram showing a planar view of a display device in a modified example two of embodiment three of the present invention;

FIG. 12 is a diagram showing a planar view of a display device in a modified example three of embodiment three of the present invention;

FIG. 13 is a diagram showing a cross-sectional view of the line A-B in a display device in embodiment four of the present invention;

FIG. 14 is a diagram showing a cross-sectional view of the line A-B in a display device in a modified example four of embodiment four of the present invention;

FIG. 15 is a diagram showing a process flow of a manufacturing method of a display device in embodiment four of the present invention;

FIG. 16 is a diagram showing a laser irradiation method of a glass frit of a display device in embodiment four of the present invention:

FIG. 17 is a diagram showing a laser irradiation method of a glass frit in a planar view of a display device in embodiment four of the present invention;

FIG. 18 is a diagram showing method of coating a glass frit in a plurality of substrate in the same process in a manufacturing process of a display device in embodiment five of the present invention;

FIG. 19 is a diagram showing method of coating a glass frit in a plurality of substrate in the same process in a manufacturing process of a display device in a modified example of embodiment five of the present invention; and

FIG. 20 is a diagram showing method of fusing a glass frit in a plurality of substrate in the same process in a manufacturing process of a display device in embodiment five of the present invention.

### DESCRIPTION OF EMBODIMENTS

Each embodiment of the present invention is explained below while referring to the drawings. Furthermore, the disclosure is merely one example and various modifications which conform with the premise of the invention and which could be easily conceived of by person ordinarily skilled in the art are included within the scope of the present invention. In addition, in order to further clarify explanation, the drawings may be expressed schematically with respect to the width, thickness and shape of each part compared to actual appearance and are only examples and do not limit the interpretation of the present invention. In addition, in the specification and each drawing the same reference symbols are attached to the same elements that have previously been described or already exist in previous drawings and therefore a detailed explanation is sometimes omitted where appropriate.

### Embodiment One

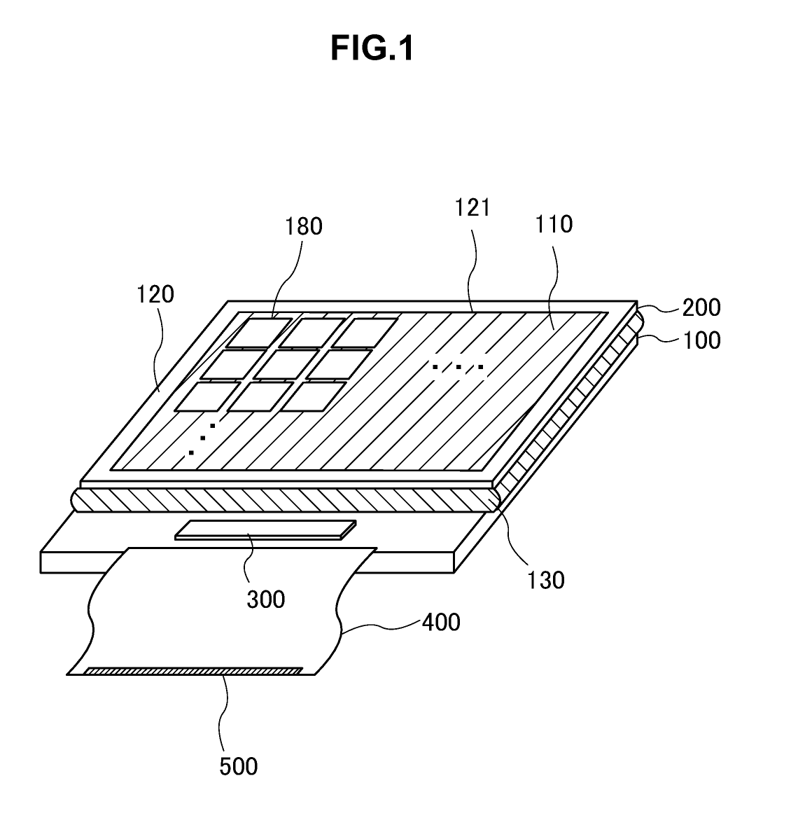

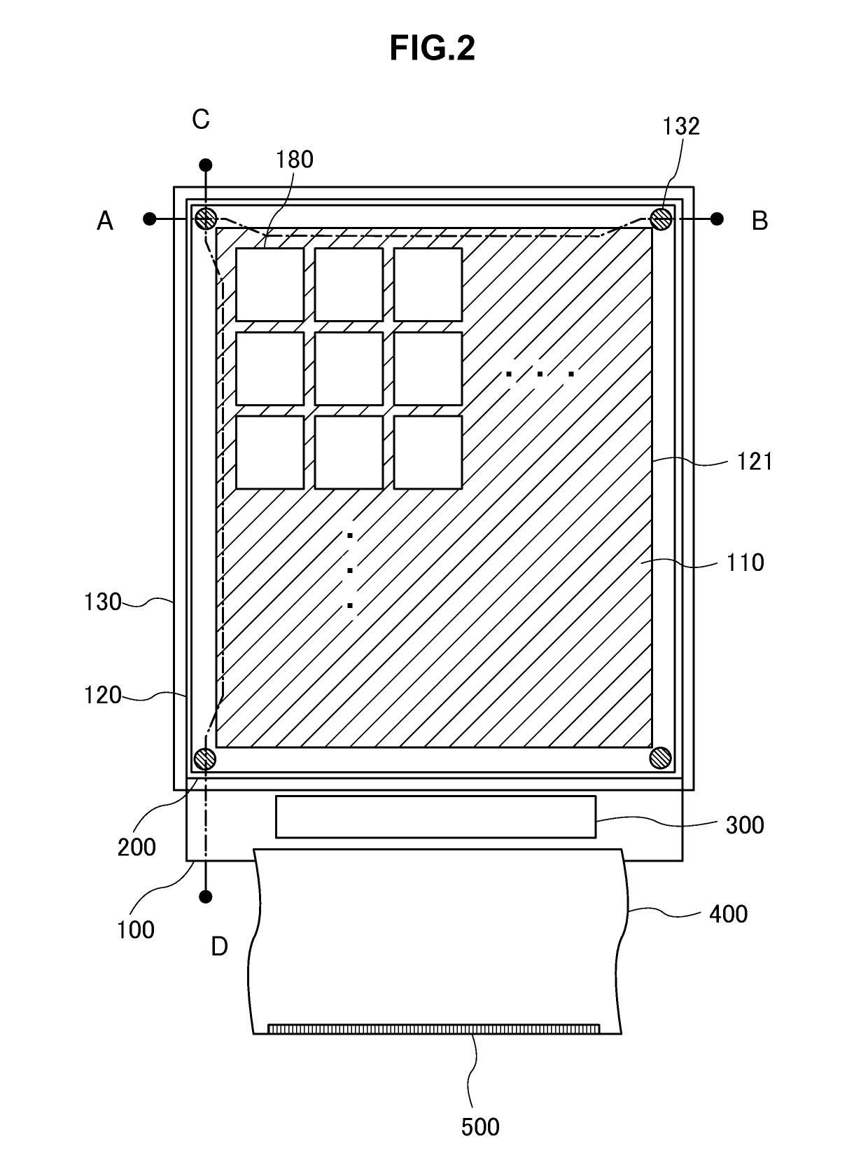

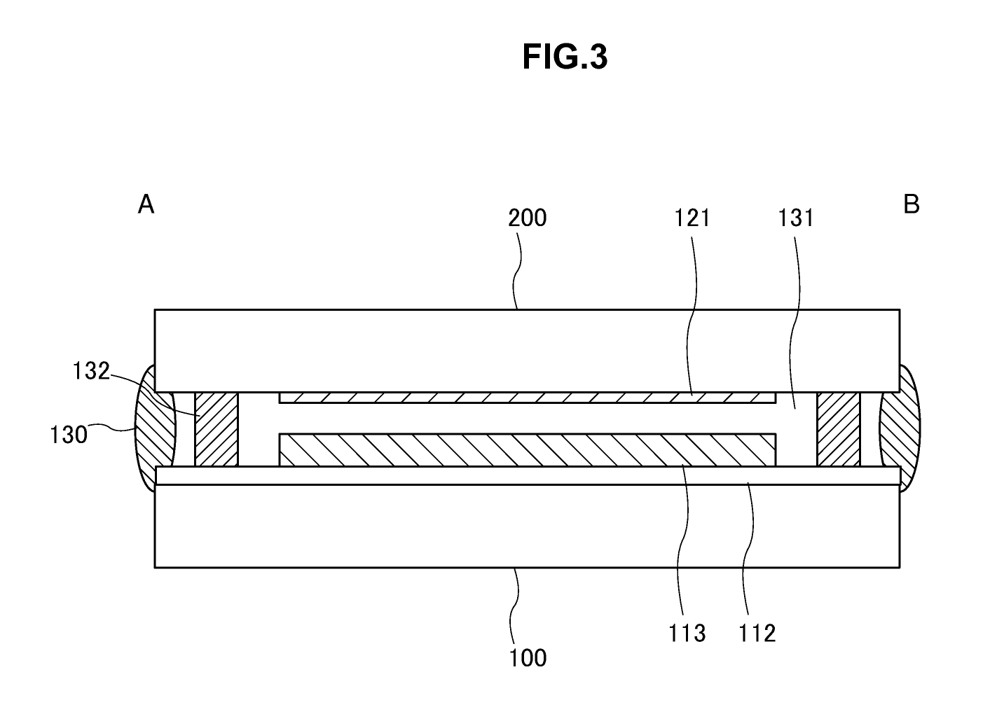

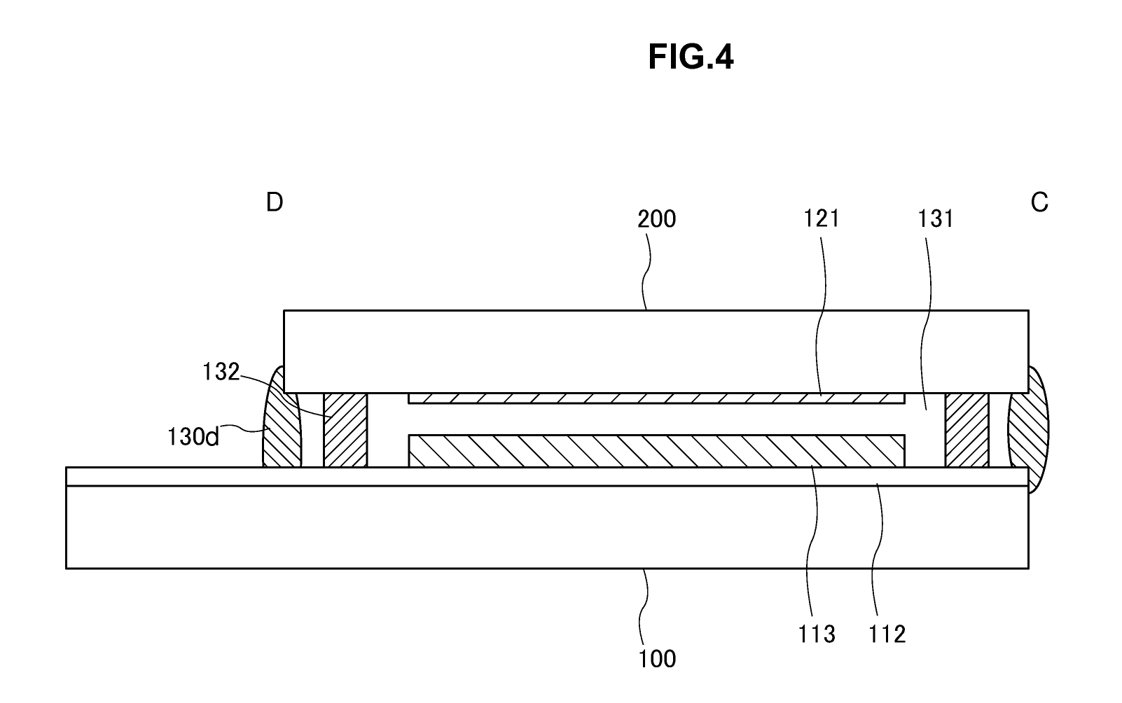

The structure of a display device related to embodiment one of the present invention is explained using FIG. 1 to FIG. 4. FIG. 1 is a diagram showing a perspective view of a display device in embodiment one of the present invention. FIG. 2 is a diagram showing a planar view of a display device in embodiment one of the present invention. FIG. 3 is a diagram showing a cross-sectional view of the line A-B in a display device in embodiment one of the present invention. FIG. 4 is a diagram showing a cross-sectional view of the line C-D in a display device in embodiment one of the present invention. In the modified examples of embodiment one and other embodiments, the line showing the cross-section in a horizontal direction is referred to as the A-B cross-sectional view and the line showing the cross-section in a vertical direction is referred to as the C-D cross-sectional view in the direction of the display device in FIG. 2.

As is shown in FIG. 1 and FIG. 2, the display device in embodiment one includes a substrate 100 including a display region 110 arranged with a plurality of pixels 180 having a light emitting element respectively, an opposing substrate 200 including a light shielding layer 121 which exposes a pixel 180, a seal member (glass frit 130) arranged in one part of a side surfaces of the substrate 100 and opposing substrate 200 and including glass which seals a space part enclosed by the substrate 100 and opposing substrate 200, a driver IC 300 arranged in a region exposed by the substrate 100, and a FPC 400 (flexible printed circuit). The substrate 100 is divided into a display region 110 and a periphery region 120 arranged in the periphery of the display region 110. The pixels 180 are arranged in a matrix in the display region 110 each of the plurality of pixels 180 is arranged with a light emitting element. The light shielding layer 121 including an aperture part corresponding to each of the plurality of pixels 180 is arranged in the opposing substrate 200. Here, a color filter including a pigment layer may be arranged in the aperture part of the light shielding layer 121. In addition, a region which is exposed by the substrate 100 and in which the driver IC 300 and FPC 400 are connected may be included in the periphery region 120. A terminal part 500 which is connected to a controller circuit which controls a drive circuit is arranged in the FPC 400.

As is shown in FIG. 2, a spacer 132 which maintains a constant interval between the substrate 100 and opposing substrate 200, and a glass frit 130 which functions as a seal member which seals a space part enclosed by the substrate 100 and opposing substrate 200 are arranged in a region corresponding to the periphery region 120. The glass frit is a glass material with a melting point of 300° C. or more and 700° C. or less. In addition, the glass frit 130 may have various forms such as a powder shape or paste shape. The glass frit 130 is arranged continuously to the exterior periphery part of a region which overlaps the substrate 100 and opposing substrate 200 so as to enclose the display region 110. In a planar view of the display device, an offset is arranged between the display region 110 and the glass frit 130.

Here, the glass frit 130 is arranged in a region sandwiched between the substrate 100 and the opposing substrate 200 and protrudes further to the exterior than an end part of the opposing substrate 200 from that region. In FIG. 2, because the opposing substrate 200 is smaller than the substrate 100, the glass frit 130 is formed along the exterior periphery of the opposing substrate 200. However, in the case where the substrate 100 is smaller than the opposing substrate 200, the glass frit 130 is formed along the exterior periphery of the substrate 100. In other words, the glass frit 130 may protrude further to the exterior than either the end of part of the substrate 100 or the opposing substrate 200.

In FIG. 2, the spacer 132 arranged in the four corners of the periphery region 120 maintains a constant interval between the substrate 100 and opposing substrate 200. In FIG. 2, although an offset is arranged between the display region 110 and spacer 132 and between the spacer 132 and glass frit 130, it is not necessary to arrange an offset as these may also be arranged to overlap. Of course, the spacer 132 may also be arranged within the display region 110. In addition, the spacer 132 may also include a function for adhering the substrate 100 and opposing substrate 200. The arrangement of the spacer is explained in detail below.

In FIG. 3, the A-B cross-sectional structure of the display device in embodiment one is explained. Here, in FIG. 3, the surface of the substrate 100 faces in the direction of the opposing substrate 200 and the surface of the opposing substrate 200 faces the direction of the substrate 100. In the following explanation, when explaining the structural components arranged with respect to each of the substrate 100 and opposing substrate 200, the surface direction of each substrate is expressed as facing upwards.

In FIG. 3, a transistor layer (not shown in the diagram) is arranged above the substrate 100, an interlayer insulation layer 112 is arranged above the transistor layer and a light emitting layer 113 is arranged above interlayer insulation layer 112. The light emitting layer 113 is arranged in the display region 110 and including a lower part electrode, a light emitting layer and upper part electrode. The lower part electrode is connected to the transistor layer via a contact arranged in the interlayer insulation layer 112 and the upper part electrode is a common electrode with a plurality of light emitting elements 113. In addition, the light shielding layer 121 is arranged above the opposing substrate 200. Here, the display device in embodiment one may be “white color+CF structure” in which a white light emitting element and color filer are combined or a “RGB painted” structure in which light emitting elements emitting RGB colors in each pixel are made separately. In the case of a “white color+CF structure”, the color filter may be arranged above the opposing substrate 200. In addition, a passivation layer may be arranged above the light emitting element in order to protect the light emitting element from water or impurities.

The spacer 132 is arranged between the substrate 100 and opposing substrate 200 and maintains a constant distance between the substrate 100 and opposing substrate 200. A material with a low degassing or low dehydration component can be used for the spacer 132, for example, it is possible to use an inorganic adhesive such as silica or ceramic.

A glass frit 130 which seals the gap pat 131 enclosed by the substrate 100 and opposing substrate 200 is arranged further to the exterior than the spacer 132. A part of the glass frit 130 is arranged so as to be sandwiched between the substrate 100 and opposing substrate 200. In addition, the glass frit 130 protrudes further to the exterior than an end part of the substrate 100 and opposing substrate 200 and is arranged so as to contact the side surfaces of the substrate 100 and opposing substrate 200. The glass frit 130 does not need to completely cover the side surface of the substrate 100 or opposing substrate 200 but may be arranged so as to contact at least one part of the side surface of the substrate 100 and opposing substrate 200.

Next, the C-D cross-sectional structure of the display device in embodiment one is explained using FIG. 4. In a part of the opposing substrate 200 on the side where the substrate 100 extends longer than the opposing substrate 200, a part of a glass frit 130d is arranged so as to be sandwiched between the substrate 100 and opposing substrate 200. In addition, the glass frit 130d protrudes further to the exterior than an end part of the opposing substrate 200 and is arranged so as to contact a side surface of the opposing substrate 200. The glass frit 130d does not need to completely cover the side surface of the opposing substrate 200 but may be arranged so as to contact at least one part of the side surface of the opposing substrate 200.

In addition, in the case where of a structure where the opposing substrate 200 extends further to the exterior than the substrate 100, in the end part of the substrate 100, the glass frit may be arranged to protrude further to the exterior than the substrate 100 and to contact a side surface of the substrate 100. In this case also, the glass frit does not need to completely cover the side surface of the substrate 100 but may be arranged so as to contact at least one part of the side surface of the substrate 100.

That is, the glass frit 130d may protrude further to the exterior than an end part of the substrate 100 or opposing substrate 200 or may be arranged so as to contact one part of a side surface of this end part. Here, although the glass frit 130 is arranged to contact the surface and side surface of the interlayer insulation later 112, the side surface of the substrate 100 and surface and side surface of the opposing substrate 200, the glass frit 130 may also be arranged to contact the surface and side surface of the substrate 100. In addition, reversely another layer may be arranged to be sandwiched between the interlayer insulation layer 112 and the glass frit 130, between the substrate 100 and the glass frit 130. In addition, another layer may be arranged to be sandwiched between the opposing substrate 200 and glass frit 130.

As described above, the glass frit 130 which seals the interval part 131 is arranged so as to protrude further to the exterior than an end part of the substrate 100 or opposing substrate 200, and by adopting a structure in which the glass frit 130 is arranged to contact a part of the side surface of the substrate 100 and opposing substrate 200, it is possible to reduce the area necessary for arranged the glass frit 130. As a result, because it is possible to narrow the periphery region 120 and widen the display region 110, it is possible obtain a narrow frame display device. In addition, by arranging the glass frit 130 so as to protrude further to the exterior than an end part of the substrate 100 and opposing substrate 200, it is possible to control irradiation of the light emitting element of the display region by passing the laser light through the glass frit 130 when irradiating a laser for fusing the glass frit 130. In addition, excess heat generated in the glass frit 130 by absorption of laser light is difficult to be transmitted to an internal light emitting element.

In addition, in embodiment one, the light emitting element 113 is exposed in the space part 131 enclosed by the substrate 100, opposing substrate 200 and glass frit 130. That is, a protection layer for protecting the light emitting layer from water or impurities is not formed above the light emitting layer 113 but the surface of the light emitting element 113 is exposed in the space part 131. For example, in the case where a light emitting element is formed from a lower part electrode, light emitting layer and upper part electrode (common electrode), a protection layer is not formed above the common electrode but a common electrode is exposed by the space part 131.

In the case of forming a passivation layer above a light emitting element, the passivation layer is also formed above wiring of a terminal part which is mounted with the driver IC 300 and FPC 400. As a result, it is necessary to remove the terminal part of the passivation layer. However, as described above, by adopting a structure in which a passivation layer is not formed above a light emitting layer, it is possible to remove not only a process for forming a passivation layer but also a process for removing the terminal part of the passivation layer.

The glass frit 130 seals the space part 131 sandwiched by the substrate 100 and opposing substrate 200. Here, in embodiment one, nitrogen (N₂) gas is filled into the sealed space part 131.

Although an inactive gas such as N₂ is filled in the space part 131, the present invention is not limited to this. For example, an atmosphere containing a low amount of water or oxygen which degrades the light emitting element 113 may almost be filled in the space part 131. For example, the atmosphere of the space part 131 is preferred to have a dew point of −70° C. or less. More preferably, a dew point of 90° C. or less. In addition, the atmosphere of the space part 131 is preferred to have an oxygen concentration of 1 ppm or less. More preferably an oxygen concentration of 0.5 ppm or less. In addition, the space part 131 may be reduced in pressure or increased in pressure. In either case, it is preferred that the contained amount of water or oxygen is small.

In addition, a film with the same material as the interlayer insulation layer 112 which contacts the glass frit 130 may be arranged above the opposing substrate 200 and a film which contacts both the top and bottom of the glass frit 130 may be made of the same material. By adopting this type of structure, because an adhesion the same as the top and bottom of the glass frit is obtained, it is possible to obtain a space part 131 with high sealing properties with a good level of reliability. Furthermore, the interlayer insulation layer 112 arranged above the glass frit 130 and an inorganic layer arranged above the opposing substrate 200 may have a structure (mirror structure) in which the glass frit is vertically symmetrical as standard. This mirror structure is referred to as a structure in which the substrate 100, silicon nitride, silicon oxide, glass frit, silicon oxide, silicon nitride and opposing substrate 200 are arranged in this order from the substrate 100 in a cross sectional view in FIG. 3 for example. Using the mirror structure described above, it is possible to obtain good reliability with high sealing properties and because stretching and contraction are reduced on the side of the substrate 100 and opposing substrate 200 which is generated by heat in a fusion process caused by laser irradiation of a glass frit etc, it is possible to relieve internal stress.

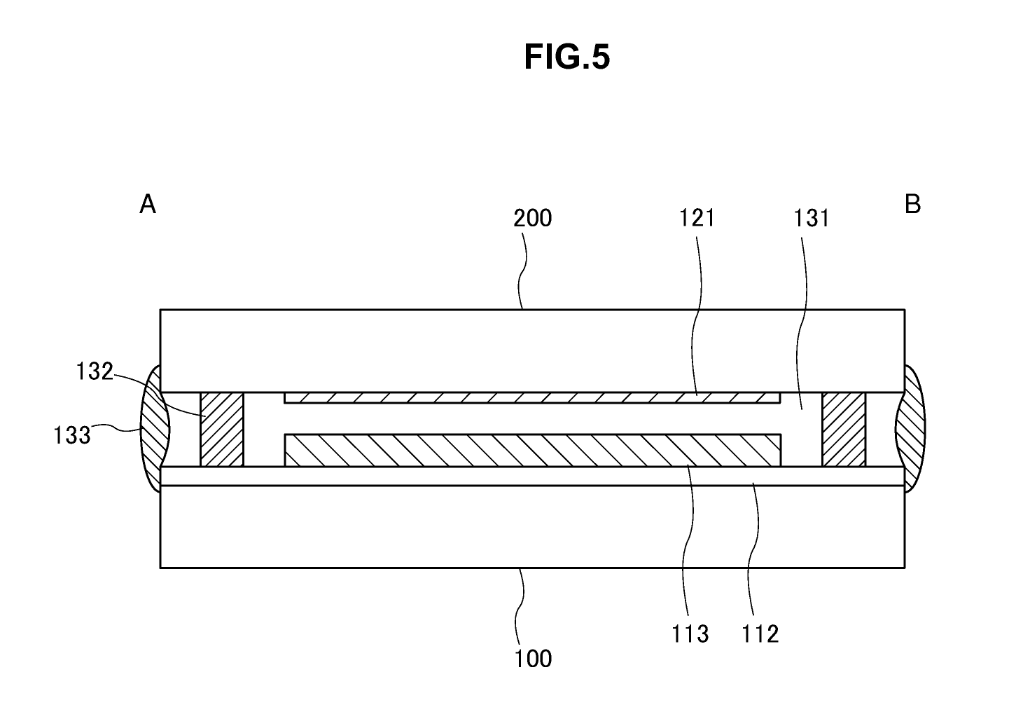

Here, a modified example one of embodiment one is explained. FIG. 5 is a diagram showing a cross-sectional view of the line A-B of the display device in a modified example one of embodiment one of the preset invention. Because FIG. 5 is similar to FIG. 3, only the different points are explained. In FIG. 5, the glass frit 133 is arranged to contact the side surface of the substrate 100, the interlayer insulation layer 112 and opposing substrate 200 and the glass frit 133 does not contact the surface were the substrate 100 and opposing substrate 200 face each other (referring to a surface above a structure in the case of a structure formed above the substrate 100 or opposing substrate). In FIG. 5, although a structure is shown in which the glass frit 133 enters further to the interior than an end part of the substrate 100 and opposing substrate 200, the present invention in not limited to this structure. For example, a structure may be adopted in which the glass frit 133 is not present between the substrate 100 and opposing substrate 200.

By adopting the structure in FIG. 5, it is possible to further reduce the area required for arranging the glass frit 133. As a result, because it is possible to narrow the periphery region 120 and widen the display region 110, it is possible to obtain a display device with a narrow frame.

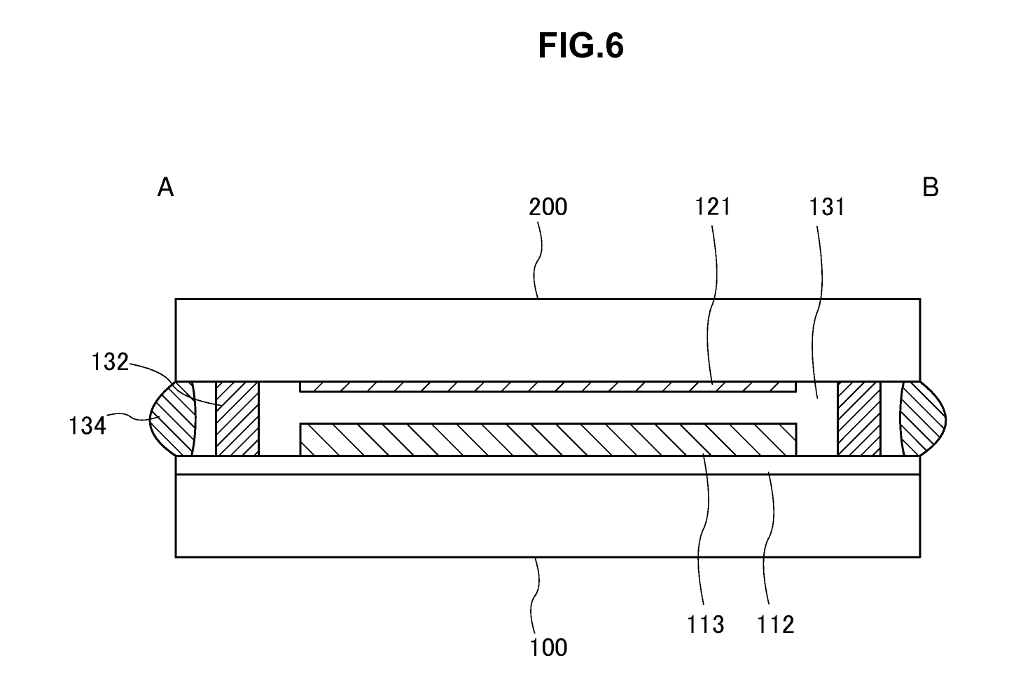

In addition, a modified example two of embodiment one is explained. FIG. 6 is a diagram showing a cross=sectional view of the line A-B of the display device in a modified example two of embodiment one of the present invention. Because FIG. 6 is similar to FIG. 3, only the different points will be explained. In FIG. 6, the glass frit 134 is arranged protruding further to the exterior than the end part of the substrate 100 and opposing substrate 200 from a position sandwiched between the substrate 100 and opposing substrate 200. The glass frit 134 does not contact with the side surface of the substrate 100, the interlayer insulation layer 112 and opposing substrate 200.

By adopting the structure in FIG. 6, it is possible to reduce the area require for arranging the glass frit 134. As a result, because it is possible to narrow the periphery region 120 and widen the display region 110, it is possible to obtain a display device with a narrow frame. In addition, although explained in detail below, it is possible to control irradiating laser light passing through the glass frit 134 onto a light emitting element of the display region when irradiating a laser for fusing the glass frit by protruding the glass frit 134 further to the exterior than the substrate 100 and opposing substrate 200. In addition, it is difficult for excess heat generated in the glass frit by absorption of laser light to be transmitted to the light emitting element in the interior.

### Embodiment Two

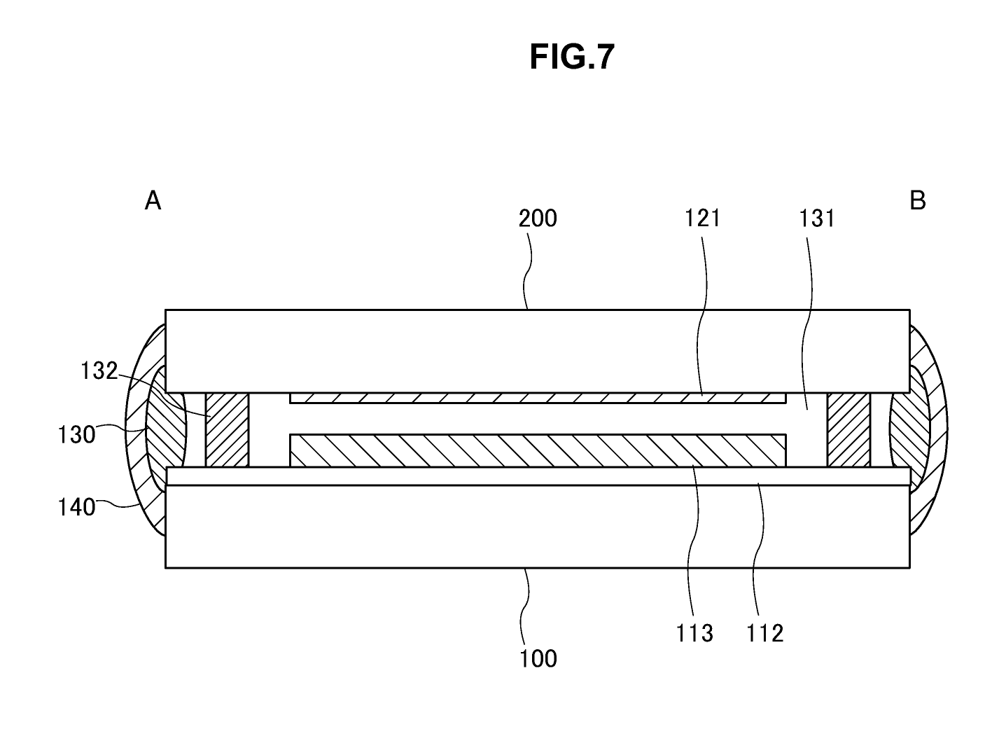

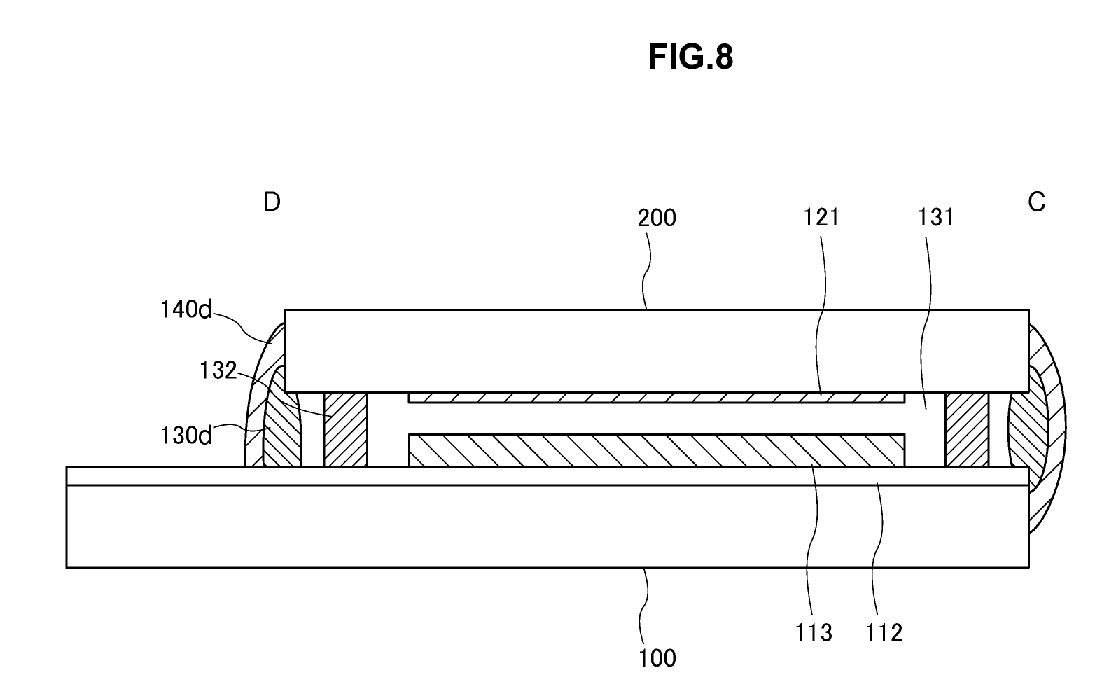

A structure of a display device related to embodiment two of the present invention is explained using FIG. 7 and FIG. 8. FIG. 7 is a diagram showing a cross-sectional structure of the line A-B of the display device in embodiment two of the present invention. In addition, FIG. 8 is a diagram showing a cross-sectional structure of the line C-D of the display device in embodiment two of the present invention.

Since FIG. 7 is similar to FIG. 3, only the different points will be explained. In FIG. 7, in addition to the structure in FIG. 3, a resin layer 140 covers the glass frit 130 as a reinforcing component, and is arranged contacting one part of the side surface of the substrate 100 and opposing substrate 200. The resin layer 140 does not need to completely cover the side surface of the substrate 100 and opposing substrate 200 and may just cover at least the glass frit 130 and contact a part of the side surface of the substrate 100 and opposing substrate 200.

Next, a cross-sectional structure of the line C-D of the display device in embodiment two is explained using FIG. 8. The resin later 140d covers the glass frit 130d on the side in which the substrate 100 extends longer than the opposing substrate 200 and is arranged to contact with the surface of the interlayer insulation layer 112 and side surface of the opposing substrate 200. The resin layer 140d does not need to completely cover the side surface of the opposing substrate 200 but may be arranged so as to contact at least one part of the side surface of these components.

In addition, in the case of a structure in which the opposing substrate 200 extends longer than the substrate 100, the resin layer 140d is arranged to cover the glass frit and contact the surface of the opposing substrate 200 and the side surface of the substrate 100 and interlayer insulation layer 112. In this case also, it is not necessary that the resin layer completely cover the side surface of the substrate 100 or interlayer insulation layer 112 but may be arranged so to contact with at least one part of the side surface of these components.

That is, resin layer 140d may be arranged to cover the glass frit and contact the side surface of the substrate 100 or opposing substrate 200 and at least one part of the side surface described above. Here, in FIG. 7 and FIG. 8, although the resin layer 140d is arranged contacting the side surface of the substrate 100 and the side surface of the opposing substrate 200, another layer may also be arranged sandwiched between the substrate 100 or the opposing substrate 200 and resin layer 140d.

As described above, by arranging a resin layer as a reinforcement component so as to cover the glass frit, the glass frit can be protected, it is possible to relive physical impacts to the glass frit and control peel of the glass frit.

### Embodiment Three

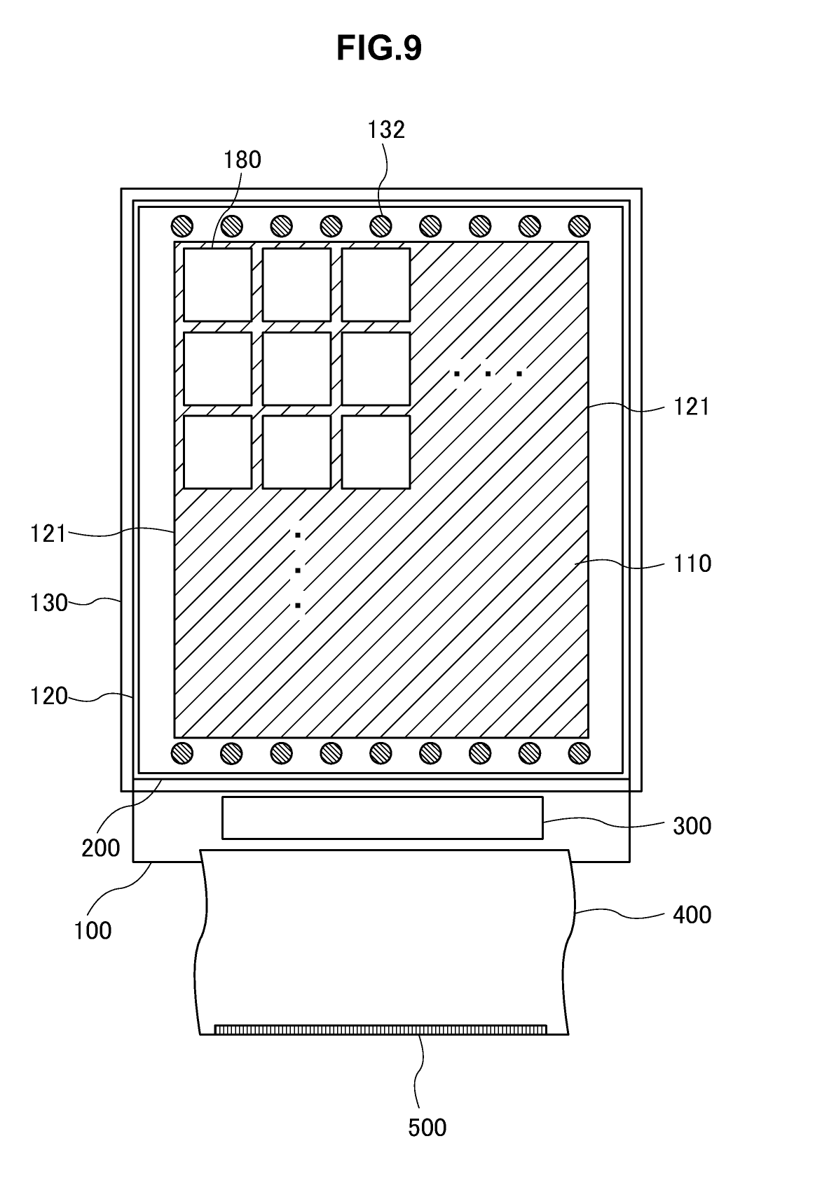

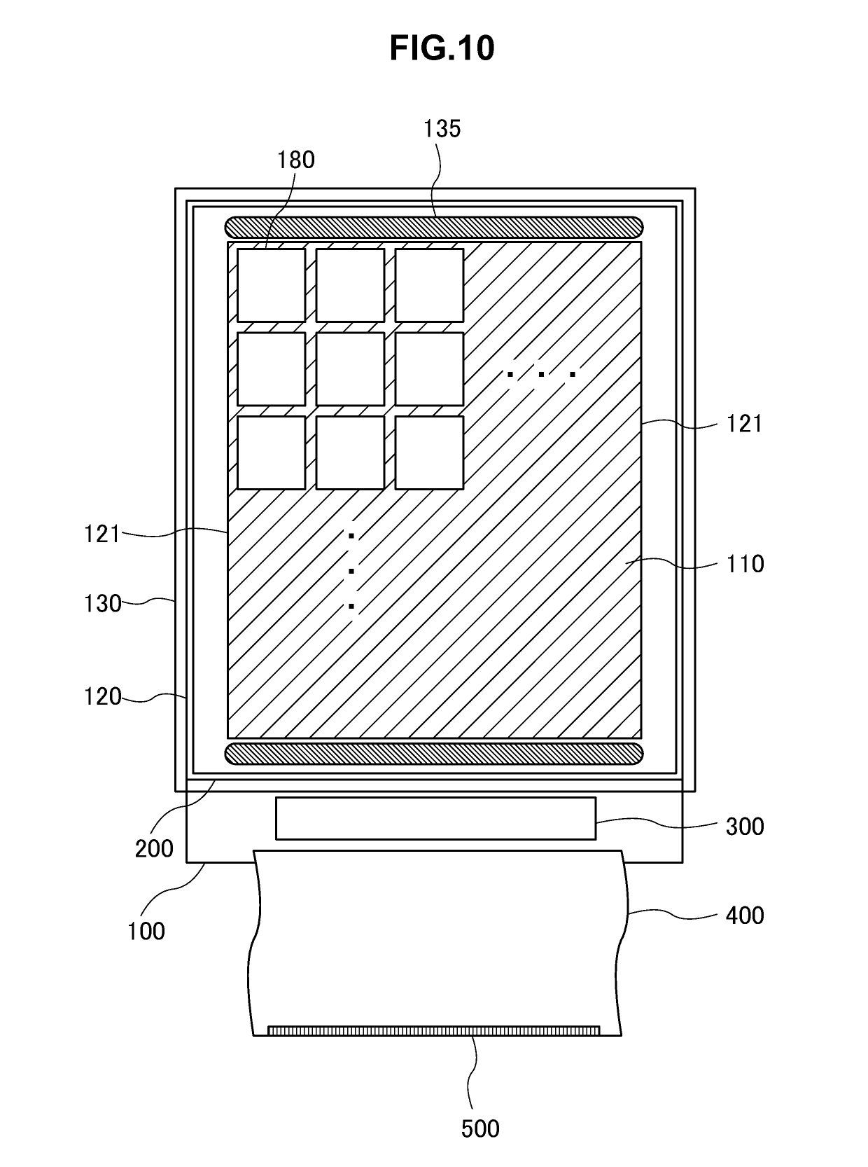

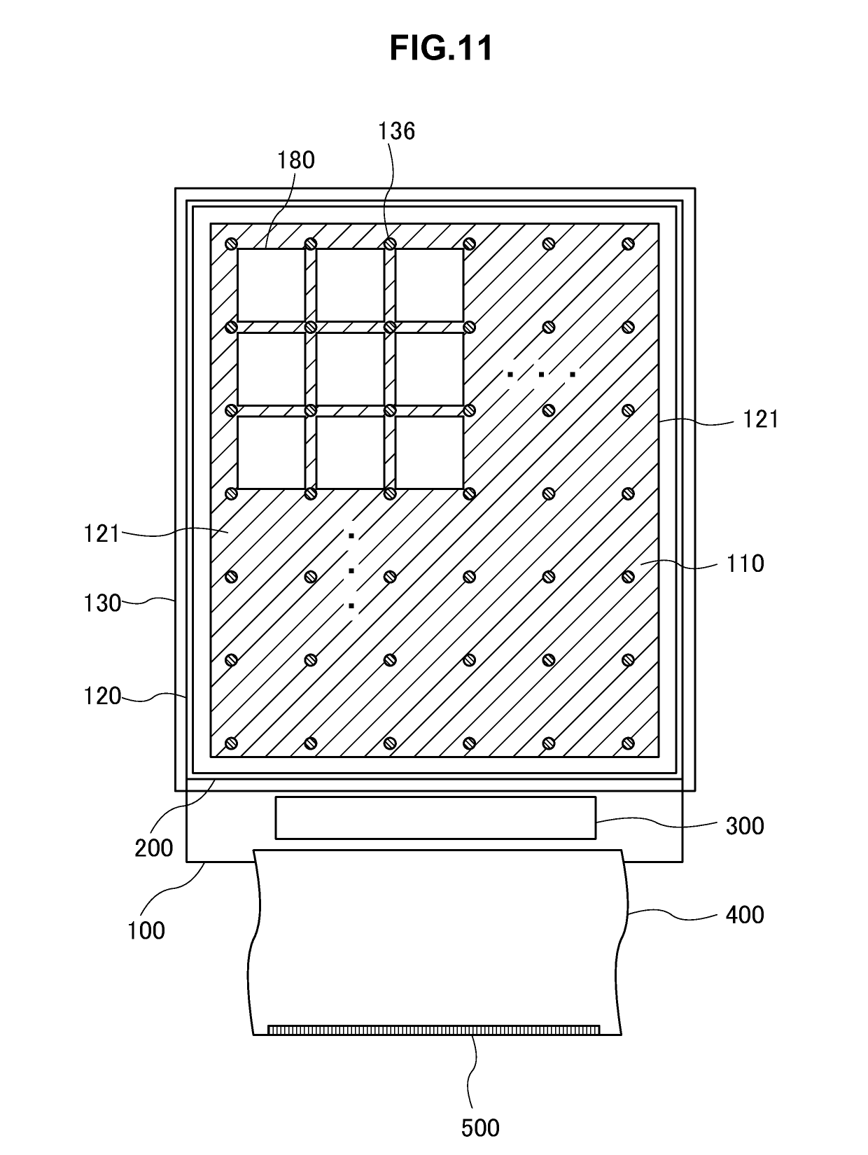

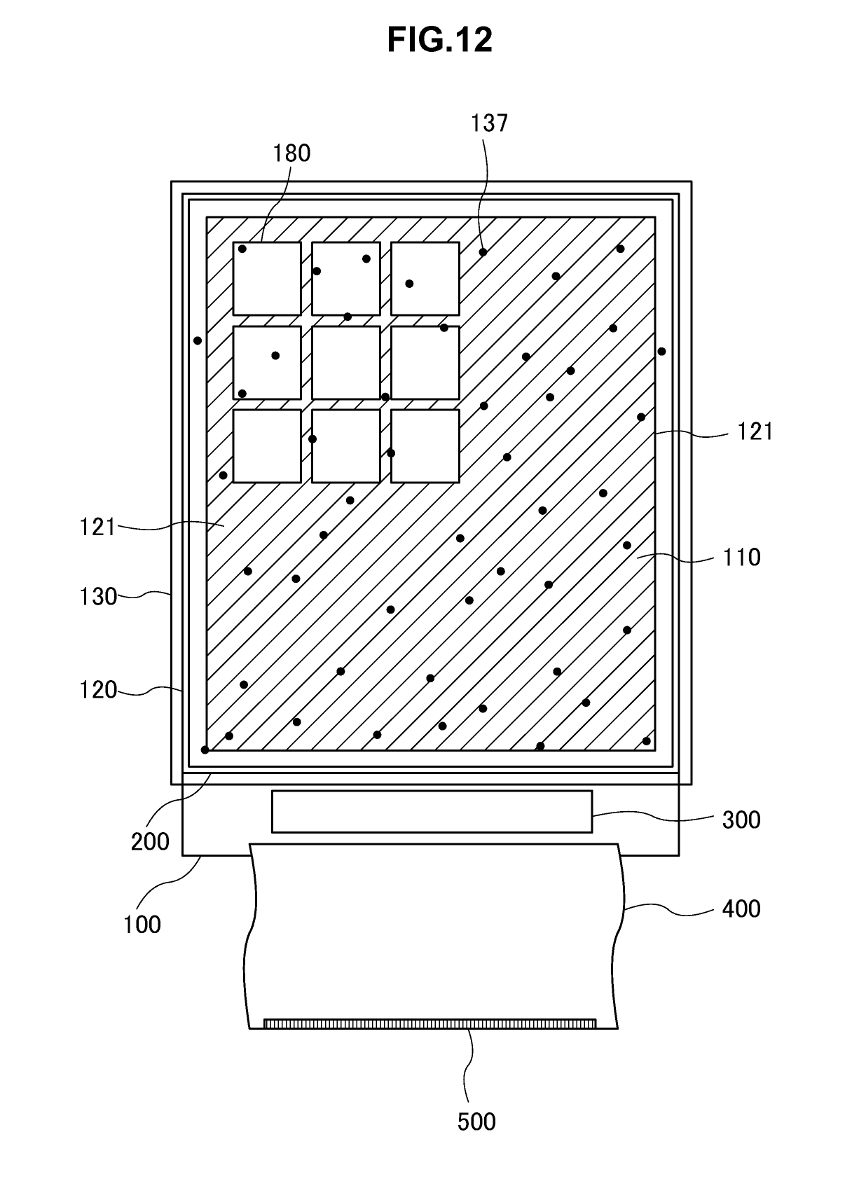

A structure of a display device related to embodiment three and a modified example are explained using FIG. 9 to FIG. 12. FIG. 9 is a diagram showing a planar view of the display device in embodiment three of the present invention. In addition, FIG. 10 is a diagram showing a planar view of the display device in a modified example one of embodiment three of the present invention, FIG. 11 is a diagram showing a planar view showing a planar view of the display device in a modified example two of embodiment three of the present invention, and FIG. 12 is a diagram showing a planar view of the display device in a modified example three of embodiment three of the present invention.

Since FIG. 9 is similar to FIG. 2 only the different points are explained. While a spacer 132 is arranged in four corners of the periphery region 120 in FIG. 2, a plurality of spacers 132 are arranged along the top and bottom edges of the periphery region 120 in FIG. 9. In addition, in FIG. 10, a spacer 135 is arranged in a shape stretching along the top and bottom edge of the periphery region 120. In this way, when it is possible to stably fix the substrate 100 and opposing substrate 200 and improve the strength with respect to external pressure after the display device is completed, by increasing the number of spacers which contact with the substrate 100 and opposing substrate 200, or by increasing the contact area with the spacer and the substrate 100 and opposing substrate 200, when the substrate 100 and opposing substrate 200 are bonded together.

In FIG. 11, a plurality of spacers 136 are arranged with the display region 110. The spacer 136 may be arranged in each pixel or arranged in a plurality of pixels. The spacer 136 may also be arranged above the light shielding layer 121 arranged between each pixel.

In addition, in Fig, 12, a plurality of particle shaped or fiber shaped spacers 137 are arranged in the display region 110 and periphery region 120. The spacer 137 may have a size which is not visible in a usual usage method of a display device, and more preferably may have a diameter of 0.5 μm or more and 10 μm or less, more preferably 1 μm or more and 5 μm or less and even more preferably 1 μm or more and 3 μm or less. In addition, the spacer 137 may also be arranged randomly in the display region 110 and the periphery region 120. The spacer 137 may also be formed using a spraying method.

As is shown in FIG. 11 and FIG. 12, by arranging spacers within the display region 110, it is possible to suppress concave parts (warping) of a substrate due to external pressure after the display device is completed, and suppress damage to an element formed in a substrate when applied with external pressure. In addition, because alignment is not necessary during formation using the spraying method shown in FIG. 12, take time is short and it is possible to form a spacer in process with a low defect occurrence ratio.

### Embodiment Four

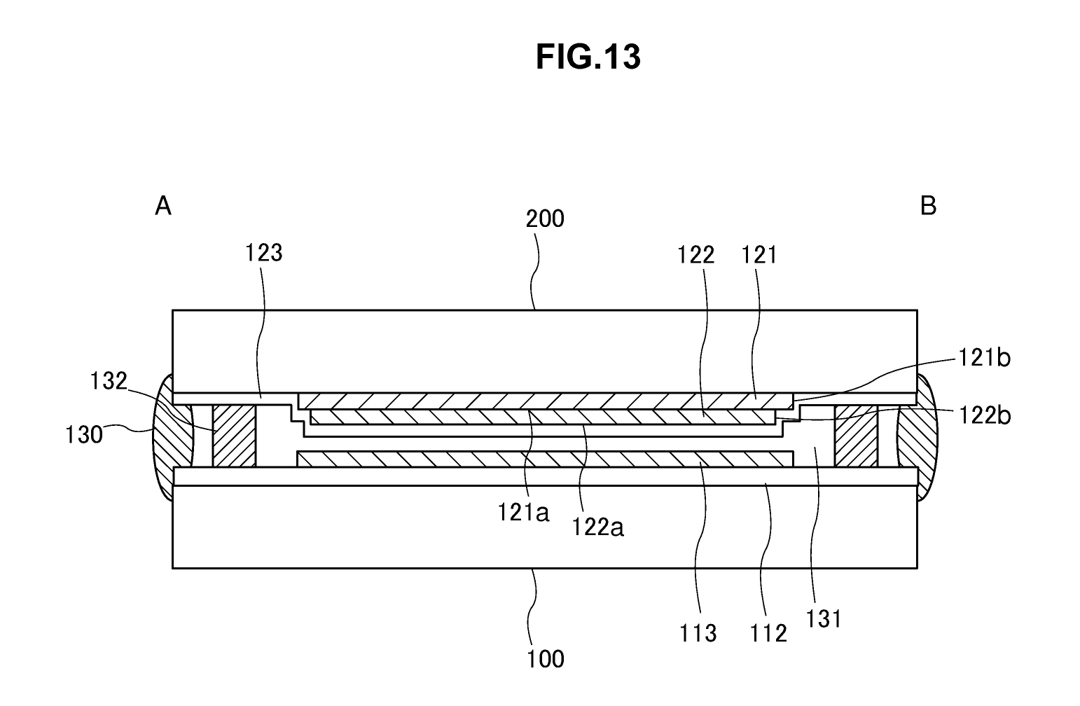

The structure of a display device related to embodiment four of the present invention is explained using FIG. 13 to FIG. 17. Embodiment four explains a structure in which a color filter is arranged above an opposing substrate when bonding a white light emitting element and a color filter “white+CF structure”.

FIG. 13 is a diagram showing a cross-sectional view of the line A-B of the display device in embodiment four of the present invention. Since FIG. 13 is similar to FIG. 3, only the different points are explained.

In FIG. 3, while a color filter 122 and inorganic passivation layer 123 are not arranged above the opposing substrate 200, in FIG. 13, a light shielding layer 121, color filter 122 and inorganic passivation later 123 are arranged above the opposing substrate 200. In particular, the color filter 122 is covered by the inorganic passivation layer 123 so as to not be exposed in the space part 131. Here, in the case where the light shielding layer 121 is an organic material, the light shielding layer 121 may be covered by the inorganic passivation layer 123 so as not to be exposed in the space part 131. Specifically, the light shielding layer 121 includes an upper surface 121a facing the substrate 100 and an end part 121b, and the color filter 122 includes an upper surface 122a which faces the substrate 100 and an end part 122b. In addition, the inorganic passivation layer 123 is arranged so as to cover 121a, 122am 121b, 122b.

Here, the light shielding layer 121 is arranged to overlap wiring etc in a region which defines each pixel and the color filter 122 is arranged in a region corresponding to each light emitting element of the display region 110. The glass frit 130 is arranged in the periphery region 120 and seals the space part 131 which is enclosed by the substrate 100 and opposing substrate 200. Here, in embodiment 1, N₂ gas is filled into the sealed space part.

Here, although the glass frit 130 is arranged contacting the interlayer insulation layer 112 and inorganic passivation layer 123, the present invention is not limited to this structure, another layer may also be arranged between the glass frit 130 and interlayer insulation layer 112 or between the glass frit 130 and inorganic passivation layer 123.

In addition, either the interlayer insulation layer 112 or inorganic passivation layer 123 or both do not have to be present, the glass frit 130 may contact with the substrate 100 or the opposing substrate 200 or both. In addition, although the light shielding layer 121, color filter 122, inorganic passivation layer 123 are stacked above the opposing substrate 200 in this order, the present invention is not limited to this. The color filter 122, light shielding layer 121, inorganic passivation layer 123 may be stacked in this order. In addition, the light shielding layer 121 and color filter 122 may have a different pattern and do not have to be stacked.

In addition, in FIG. 13, although the substrate 100 and interlayer insulation layer 112 are in contact, the interlayer insulation layer 112 and light emitting element 113 are in contact, the opposing substrate 200 and light shielding layer 121 are in contact, the light shielding layer 121 and color filter 122 are in contact, and the color filter 122 and inorganic passivation layer 123 are in contact, the present invention is not limited to this structure, another layer may be inserted between each of these.

In addition, in embodiment four, the light emitting element 113 is exposed in the space part 131 enclosed by the substrate 100, opposing substrate 200 and glass frit 130. That is, a protection layer for protecting the light emitting layer from water or impurities is not formed above the light emitting element 113 but the surface of the light emitting element 113 is exposed in the space part 131. For example, in the case where a light emitting element is formed from a lower part electrode, light emitting layer and upper part electrode (common electrode), a protection layer is not formed above the common electrode but a common electrode is exposed in the space part 131.

As described above, by adopting the structure in FIG. 13, it is possible to reduce the area of the region arranged with glass frit 130 and obtain a display device with a narrow frame. In addition, by adopting a “white color+CF structure” it is possible to realize a display device with a very high definition. Furthermore, by arranging a color filter between the substrates, it is possible to realize a high quality display device which can suppress mixed colors caused by light entering from a light emitting element of an adjacent pixel. In addition, by adopting a structure in which a passivation layer is not arranged above a light emitting element, it is possible to reduce the process of forming a passivation layer of a terminal part as well as the process for forming as passivation layer.

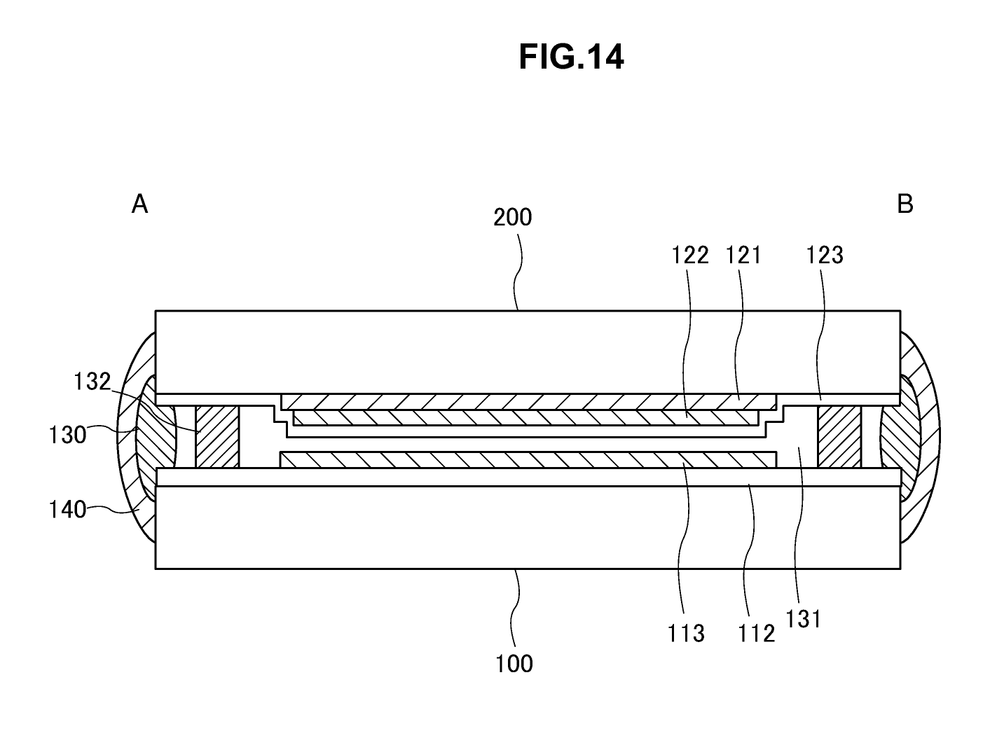

FIG. 14 is a diagram showing a cross-sectional structure of the line A-B of the display device in a modified example embodiment four of the present invention. In addition to the structure in FIG. 13, in FIG. 14 a resin layer 140 is covers the glass frit 130 as a reinforcement component and is arranged to contact a part of the side surface of the substrate 100 and opposing substrate 200. The resin layer 140 does not need to completely cover the side surface of the substrate 100 or opposing substrate 200 but may be arranged so as to cover at least the glass frit 130 and contact a part of the side surface of the substrate 100 or opposing substrate 200.

As described above, similar to the embodiment two, by arranged a resin layer as a reinforcement component so as to cover the glass frit, it is possible to protect the glass frit and relieve physical stress to the glass frit. In addition, it is possible to suppress peeling of the glass frit.

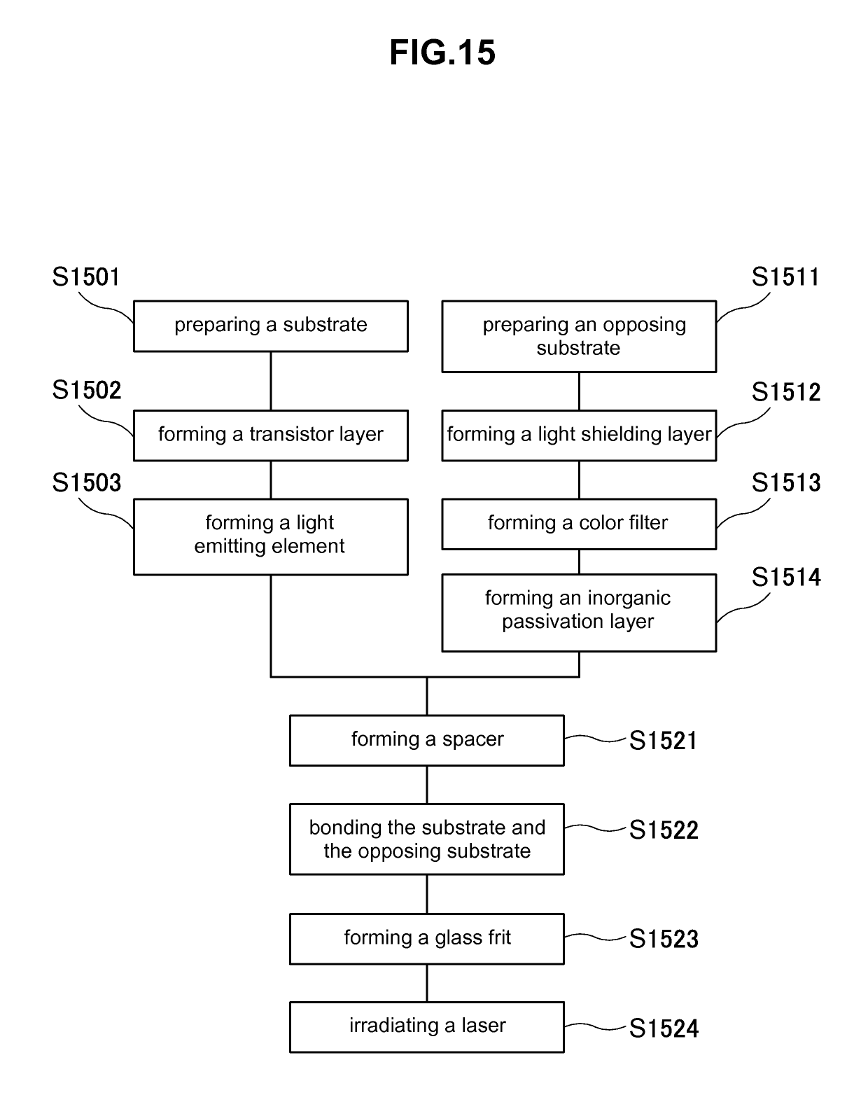

FIG. 15 is a diagram showing a process flow chart of a manufacturing method of the display device in embodiment four of the present invention. The manufacturing method of the display device in embodiment four is explained using FIG. 15.

First, a substrate such as a glass substrate is prepared (S1501) and a transistor layer is formed above the substrate (S1502). It is possible to use a general transistor as the transistor layer, for example, a bottom gate type transistor or top gate type transistor using amorphous silicon, polysilicon or oxide semiconductor etc. Before forming the transistor layer, a single or stacked ground layer which blocks impurities from the glass substrate may be formed in order to improve adhesion. Next, after forming the transistor layer, a single or stacked interlayer insulation layer is formed, and a light emitting element is formed in a display region arranged with a plurality of pixels (S1503). The light emitting element is obtained by formed a bottom electrode connected to a transistor layer via a contact formed in the interlayer insulation film, a light emitting layer is formed above the bottom electrode, and a common electrode common to a plurality of light emitting elements is formed above the light emitting layer.

Next, an opposing substrate such as a glass substrate is prepared (S1511) and a light shielding layer which exposes a pixel is formed above the opposing substrate (S1512). A metal such as Cr or a resin material pigmented in black may be used as the light shielding layer. The light shielding layer is formed in the display region and the periphery region. The light shielding layer is formed in a region which defines each pixel in the display region so as to overlap wiring etc, and formed in a region between the display region and glass frit in the periphery region.

Next, a color filter including a pigment layer is formed in an aperture part arranged in the light shielding layer of the opposing substrate (S1513). The color filter is formed in the display region and is formed in a region corresponding to each light emitting element. At least a R (red), G (green) and B (blue) color filter are formed for realizing full color. In addition, a white color filter may be formed for improving color reproduction in a white color pixel arranged for improving luminosity.

Although a manufacturing method for forming a color filter above light shielding layer was explained in FIG. 15, the present invention is not limited to this structure. The color filter may be formed first and then the light shielding layer may be formed above the color filter. In addition, another layer may be formed between the opposing substrate and light shielding layer or color filter, or another layer may be formed between the light shielding layer and the color filter. In addition, although at least three types of color filter RGB are formed as the color filter, a light shielding layer may be formed between any of the three types of color filter. For example, first the R G color filters may be formed above the opposing substrate, the light shielding layer may be formed above the RG color filters then the B color filter may be formed above these.

After forming the light shielding layer, an inorganic passivation layer is formed so as to cover the upper surface and end parts above light shielding layer and color filter (S1514). Because the inorganic passivation layer covers an organic layer which discharges any gas or water which leads to degradation of a light emitting element, the inorganic passivation layer may be formed at least so that color filter is not exposed in the space part 131. In the case where the light shielding layer is formed from a resin, the inorganic passivation layer is formed so that both the color filter and light shielding layer are not exposed in the space part 131. That is, as is shown in FIG. 13, the light shielding layer 121 includes an upper surface 121a facing the substrate 100 and end part 121b, the color filter 122 includes an upper surface 122a facing the substrate 100 and an end part 122b, and the inorganic passivation layer 123 is arranged so as to cover 121a, 122a, 121b and 122b.

Next, a spacer is formed above the substrate formed up to a light emitting element or either the opposing substrate formed up to the inorganic passivation layer or both substrates (S1521). The spacer can be formed by a method for forming a column shaped spacer in a desired position, a method for spraying a particle shaped or fiber shaped spacer of a constant size or various other methods for example as is explained in embodiment three. In whichever method, it is possible to use a low dehydration or degassing material for the material of the spacer, for example, it is possible to use an inorganic adhesive such as silica or a ceramic. In the case where a spacer is formed in the opposing substrate, a convex part may be arranged in a part of the inorganic passivation layer as the spacer. After forming the spacer, both substrates are bonded so that the display region and color filter are facing each other (S1522). Although not shown in the diagram, cutting is performed in order to separate the large substrate into separate panels according to necessity.

After both substrates are bonded, a glass frit is formed using a coating method such as dipping or inkjet method from the side surface of both substrates (S1523). The space part enclosed by the substrate and opposing substrate is sealed so that the glass frit protrudes further to exterior than the end part of the substrate formed with a light emitting element or opposing substrate. In the present invention, after bonding the substrate, the glass frit is formed from the side surface of the pair of substrates. Therefore, it is possible to prepare a plurality of pairs of substrates and form the glass frit in the same process on the side surface of these substrates. Here, as is shown in FIG. 3, the glass frit is formed so as to contact the side surface of the substrate or opposing substrate. However, there is no need for the glass frit to be formed to completely cover the substrate or side surface but may be formed to contact at least a part of the side surface of these

Here, it is very important that the atmosphere filled into the space part sealed by the substrate, opposing substrate and glass frit when the glass frit is formed. In embodiment four, the formation of the glass frit is performed under an atmosphere of N₂. However, the present invention in not limited this. The atmosphere in the process for forming the glass frit may be an atmosphere so that the contained amount of water or oxygen which leads to degradation of a light emitting element is small. For example, the atmosphere for forming the glass frit is preferred to have a dew point temperature of −70° C. or less and more preferably −90° C. or less. In addition, the atmosphere for forming the glass frit is preferred to have an oxygen concentration of 1 ppm or less and more preferably 0.5 ppm or less. In addition, the atmosphere for forming the glass frit may be under a reduced pressure or reversely under added pressure. In either case, the atmosphere when bonding both substrates is preferred to have a small contained amount of water or oxygen.

Finally, the glass frit formed on the bonded substrates is heated locally using laser irradiation (S1524). By locally heating the glass frit, the glass frit is fused to a pair of substrates or an inorganic layer formed above a pair of substrates and the light emitting element is sealed. Here, the glass frit may include a pigment which absorbs the energy of the laser light wavelength band in order to effectively absorb the laser light and emit heat.

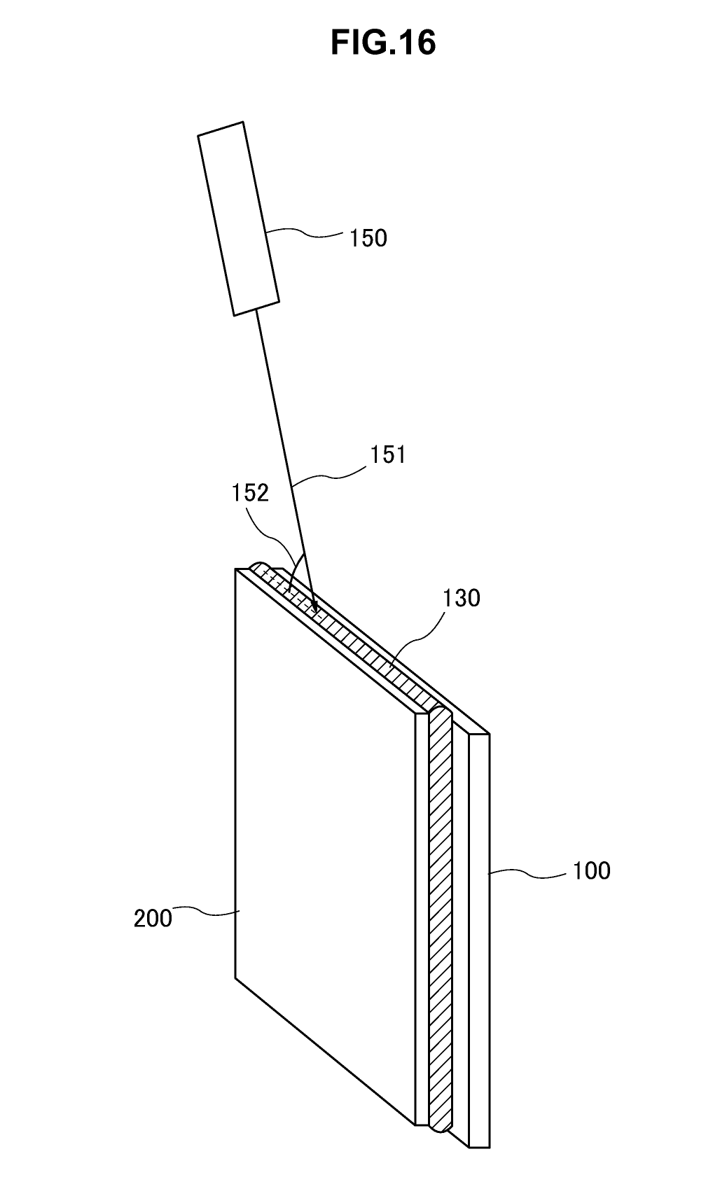

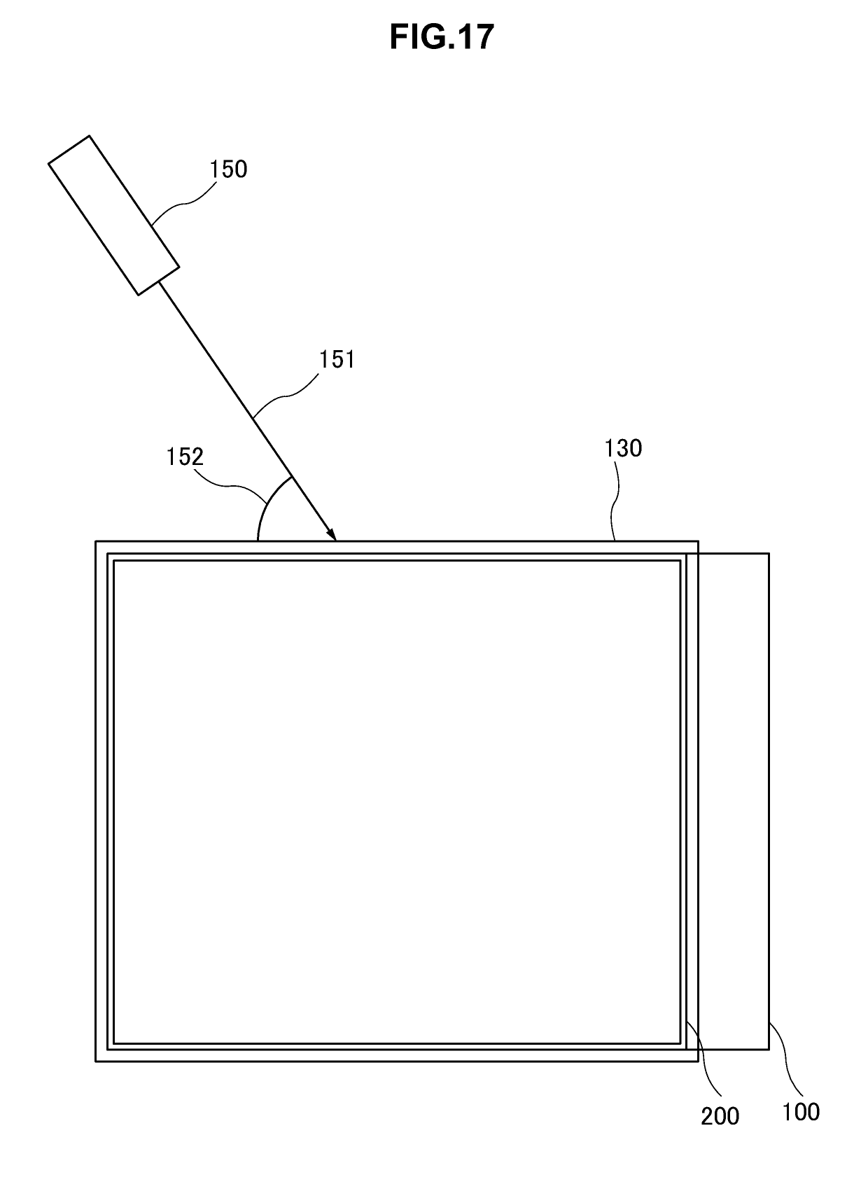

Next, a more specific method of the laser irradiation process is explained using FIG. 16 and FIG. 17. FIG. 16 is a diagram showing a laser irradiation method of a glass frit of a display device in embodiment four of the present invention. In addition, FIG. 17 is a diagram showing a method of laser irradiation of a glass frit in a planar view of the display device in embodiment four of the present invention. Laser irradiation in the present invention is performed by irradiating layer light 151 emitted from a light source 150 onto a side surface of the substrate 100 and opposing substrate 200 and fusing the glass frit 130. Here, the laser light 151 is irradiated roughly parallel to the surface of the substrate 100 and opposing substrate 200. In addition, in a planar view of the substrate 100 and opposing substrate 200, the laser light 151 is irradiated so as to formed a perpendicular angle and sharp angle 152 with respect to one side of the substrate 100 and opposing substrate 200. This angle 152 is preferred to be 30° or more and 90° or less and more preferably 45° or more and 90° or less.

As described above, by irradiating laser light 151 roughly parallel onto the surface of the substrate 100 and opposing substrate 200, it is possible to irradiate the leaked light which is not irradiated on the glass frit onto the light emitting element within the display region and suppress degradation of the light emitting element. In addition, by irradiating the laser light 151 at a sharp angle 152 on one side of the substrate 100 and opposing substrate 200, it is possible to lengthen the light wavelength within the glass frit of the laser light 151. In addition, it is possible to control irradiating a part of the laser light 151 passing through the glass frit and suppress it from reaching the light emitting element of the display region.

### Embodiment Five

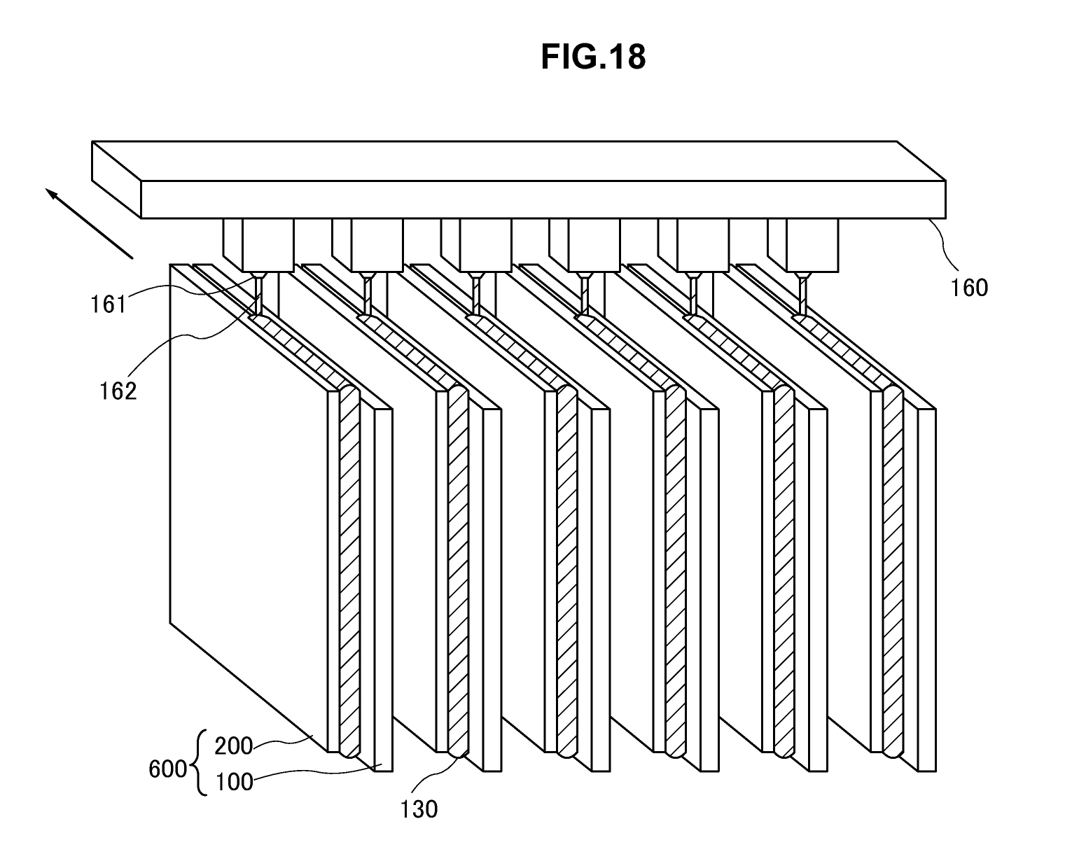

A manufacturing method of a display device in embodiment five of the present invention is explained using FIG. 18 to FIG. 20. Embodiment five explains a method in which a plurality of pair of substrates 600 bonded together using the substrate 100 and opposing substrate 200 are aligned and a glass frit 130 is formed with respect to the plurality of pair of substrates 600.

FIG. 18 is a diagram showing method of coating a glass frit in a plurality of substrates in the same process in a manufacturing process of a display device in embodiment five of the present invention. First, the plurality of pair of substrates 600 are aligned so that their surfaces mutually overlap. In FIG. 18, although a spacer is arranged between each pair of substrates 600, each pair of substrates 600 may be aligned so as to mutually contact each other.

A plurality of nozzles 161 which spray a liquid glass frit are arranged in a fixed jig 160 corresponding to an arrangement interval of the plurality of pair of substrates 600. The fixed jig 160 scans the nozzle 161 in the direction shown by the arrow in FIG. 18. As is shown in FIG. 18, by operating the fixed jig 160 and nozzle 161 in the direction of the arrow while spraying a liquid column 162 of the glass frit material from a fine hole, the glass frit 130 is coated consecutively on an interface part of the substrate 100 and opposing substrate 200. After the glass frit 130 is coated on one side of a pair of substrate 600, the pair of substrates 600 are rotated 90 degrees and the side adjacent to the side coated with glass frit 130 is arranged so as face the direction of the nozzle 161. In addition, the same as described above, the glass frit 130 is coated on the side surface of the pair of substrates 600.

Coating of the glass frit 130 may be performed while rotating a plurality of the pairs of substrates 600. In this case, the fixed jig 160 may be arranged vertically so as to maintain a constant distance between the nozzle tip end and the side surface of the pairs of substrates 600 coated with the glass slit 130.

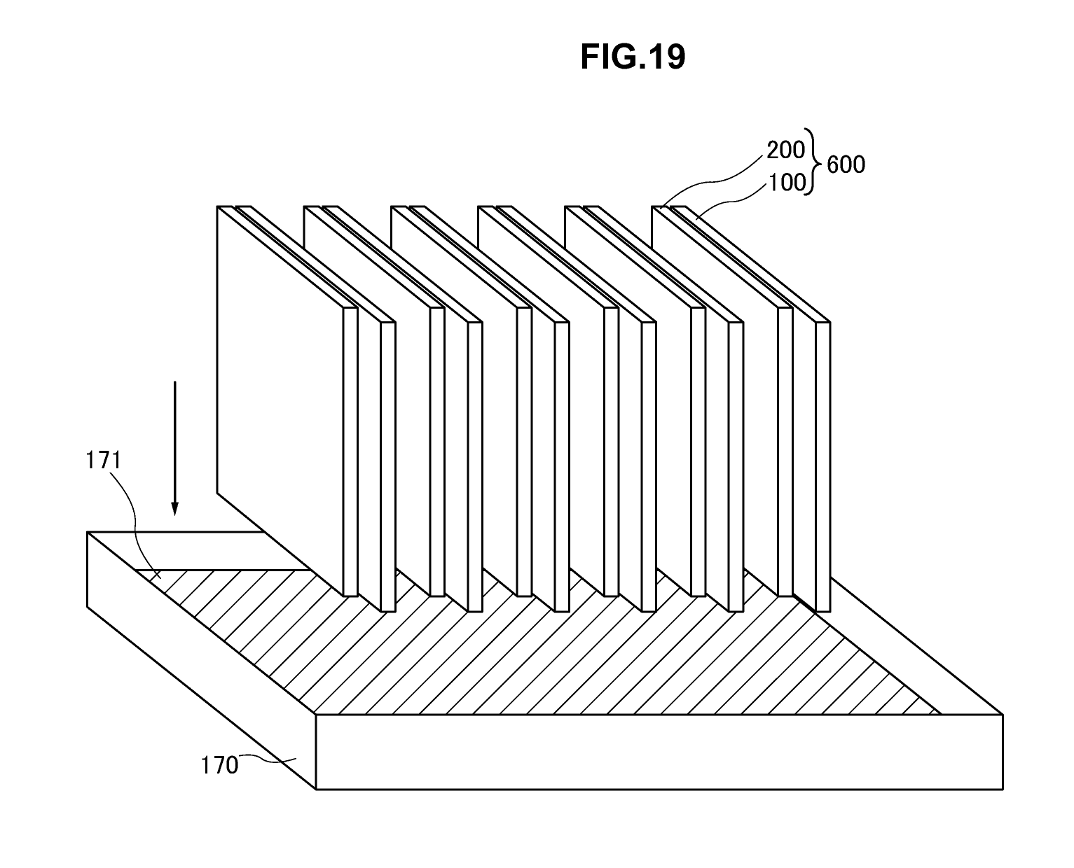

FIG. 19 is a diagram showing method of coating a glass frit in a plurality of substrate in the same process in a manufacturing process of a display device in a modified example of embodiment five of the present invention. In FIG. 19, the plurality of pair of substrates 600 are immersed in a container 170 containing a glass frit material 171 and the glass frit is formed by what is called a dipping method. In this case, regions where the glass frit is to be formed may include lyophilic with respect to the glass frit material 171. Furthermore, the other regions may include water repellency with respect to the glass frit material 171. By adopting this structure, it is possible to form a glass flit in a desired region even in the case of forming a glass frit using a dipping method.

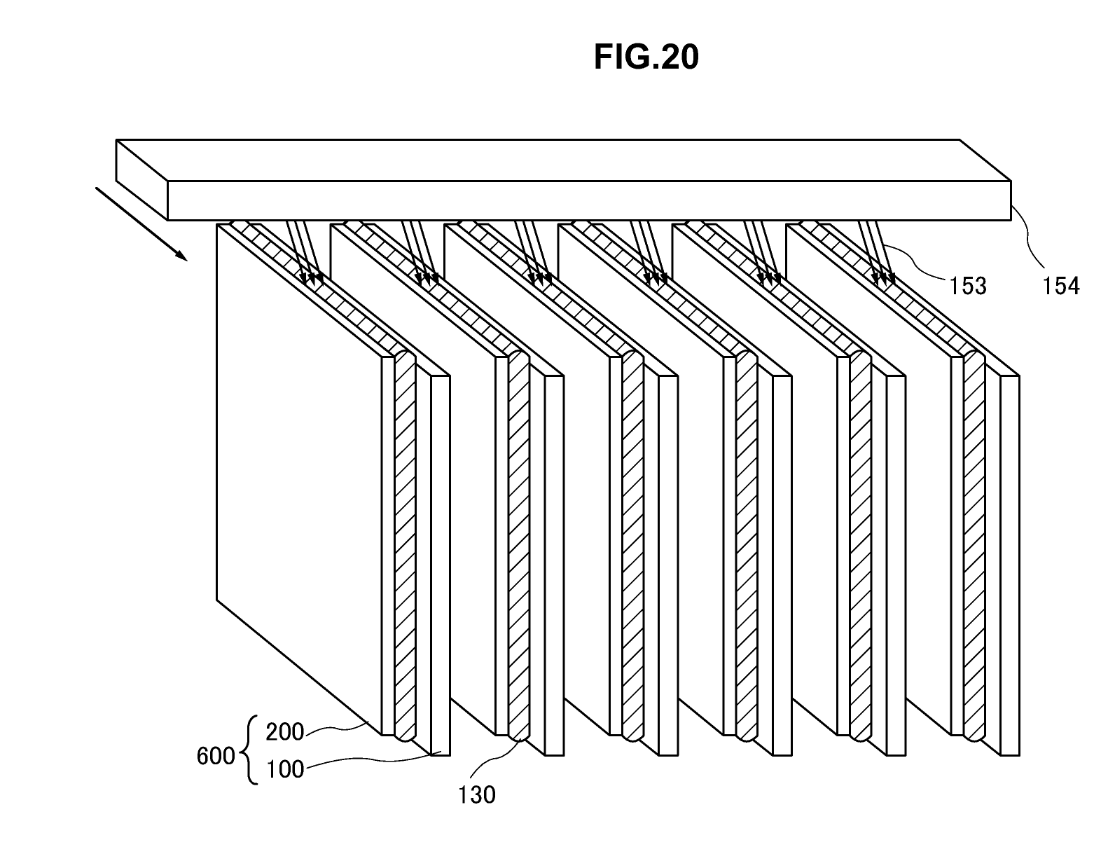

FIG. 20 is a diagram showing method of fusing a glass frit in a plurality of substrate in the same process in a manufacturing process of a display device in embodiment five of the present invention. Similar to FIG. 18, the surfaces of the plurality of pair of substrates 600 are aligned so as to mutually overlap. Then, a light source group 154 which emits a plurality of laser lights 153 is arranged corresponding to an arrangement interval of the plurality of pair of substrates 600. The light source group 154 is scanned in the direction of the arrow shown in FIG. 20 and a laser light 153 is irradiated on the glass frit 130 coated on a side surface of a pair of substrates 600. A glass frit is locally heated by irradiating the laser light 153 and fused to the side surface of the substrate 100 and opposing substrate 200. Here, the angle at which the laser light 153 is irradiated is preferred to be the angle shown in FIG. 16 and FIG. 17.

As is shown in FIG. 20, the light source group 154 is operated in the direction of the arrow while irradiating the plurality of laser lights 153 on the glass frit formed on the side surface of the plurality of pairs of substrates 600 and the glass frit 130 is fused to one side of the plurality of pairs of substrate 600. Next, a pair of substrates 600 is rotated 90 degrees and the side adjacent to the side fused with the glass frit 130 is arranged so as to face the direction of the light source group 154. Then, as described above, the laser light 153 is irradiated on the glass frit 130.

According to the method described above, it is possible to form a glass frit in the same process with respect to a plurality of pairs of substrates and fuse the glass frit in the same process. In this way, take time can be improved and it is possible to reduce manufacturing costs.

Furthermore, the present invention is not limited to the embodiments described above and can be appropriately modified without departing from the scope of the invention.

What is claimed is:

1. A display device comprising:
a first substrate comprising a display region arranged with a plurality of pixels having a light emitting element respectively;
a second substrate facing the first substrate;
a spacer arranged between the first substrate and the second substrate; and
a seal component comprising glass, bonding together the first substrate and second substrate, arranged on the exterior side of the display region and protruding further to the exterior side than an end part of the first substrate or second substrate.

2. The display device according to claim 1, wherein the seal component is arranged on one part of a side surface of the first substrate or second substrate.

3. The display device according to claim 2, wherein the seal component is sandwiched between the first substrate and second substrate.

4. The display device according to claim 3, wherein the spacer is formed from an inorganic material.

5. The display device according to claim 1, wherein the second substrate comprises a light shielding layer having an aperture part corresponding to the pixel, a color filter comprising a pigment layer and being arranged at least in the aperture part and an inorganic insulation layer covering at least the upper surface and an end part of the color filter;
wherein
the seal component bonds the first substrate and second substrate, the display region and color filter facing each other;
the color filter is arranged on the interior side of the seal component; and
the light emitting element is exposed in a space part enclosed by the first substrate, the second substrate and seal component.

6. The display device according to claim 5, further comprising:
a resin layer covering the seal component and arranged contacting a part of a side surface of the first substrate or second substrate.

7. The display device according to claim 5, wherein a dew point temperature of the space part is −70° C. or less.

8. The display device according to claim 7, wherein an oxygen concentration of the space part is 1 ppm or less.

9. A manufacturing method of a display device comprising:
forming a light emitting element in a display region arranged with a plurality of pixels in a first substrate;
bonding the first substrate and a second substrate facing the first substrate via a spacer;
forming a seal component comprising glass, the seal component being arranged on the exterior side of the display region and protruding further to the exterior than and end part of the first substrate or second substrate;
irradiating a laser from a surface side of the first substrate or second substrate to fuse the seal component.

10. The manufacturing method of a display device according to claim 9, wherein the seal component is formed on a part of a side surface of the first substrate or second substrate.

11. The manufacturing method of a display device according to claim 10, wherein the seal component is sandwiched by the first substrate or second substrate.

12. The manufacturing method of a display device according to claim 11, wherein the laser is irradiated roughly parallel on a surface of the first substrate and second substrate.

13. The manufacturing method of a display device according to claim 12, wherein the laser is irradiated so as to form a sharp angle with respect to one edge of the first substrate and second substrate in a planar view of the first substrate and second substrate.

14. The manufacturing method of a display device according to claim 9, wherein a plurality of lasers are irradiated in the same process on a plurality of pairs of substrates formed by bonding a plurality of the first substrates and a plurality of second substrates.

15. The manufacturing method of a display device according to claim 14, wherein a plurality of the seal components is formed in the same process on a plurality of pairs of substrates.

16. The manufacturing method of a display device according to claim 15, wherein the seal component is formed under an atmosphere in which a dew point temperature is −70° C. or less

17. The manufacturing method of a display device according to claim 16, wherein the seal component is formed under an atmosphere in which an oxygen concentration is 1 ppm or less.
